(19) United States
(12) Patent Application Publication
(10) Pub. No.: US 2005/0082949 A1
(43) Pub. Date: Apr. 21, 2005

(54) Piezoelectric generator

(76) Inventor: Michio Tsujiura, Shizuoka (JP)

Correspondence Address: ANDERSON, KILL & OLICK, P.C., 1251 AVENUE OF THE AMERICAS, NEW YORK,, NY, 10020-1182, US

(21) Appl. No.: 10/691,185

(22) Filed: Oct. 21, 2003

(51) Int. Cl. H01L 41/113

(52) U.S. Cl. 310/339

(57) ABSTRACT

A power generation and transmission system of conventional technology has public hazard issues associated with long distance transmission of water power, thermal power, and atomic power accompanied by energy losses. A power generation method utilizing natural energy such as solar, wind, and the like, also has a problem in scaling and stability of power generation capacity. The present invention utilizes a large number of piezoelectric elements and controls electric discharges to provide power in a stable and highly efficient manner. It provides a power generation system according to demand of factories in a hazard free and transmission system free manner.

### TECHNICAL FIELD

The present invention relates to an electric power generator and more particularly to a piezoelectric ceramic electric power generator.

### RELATED ART

The ability of a piezoelectric ceramic to generate power upon an impact or application of a similar mechanical force thereto is known to the public. However, the levels of power generated were believed to be small static charges.

### PROBLEMS TO BE SOLVED

Lately, as environmental contamination is a serious social concern, energy conservation type power generators such as wind mill power generators or fuel cells have been rigorously developed. A piezoelectric ceramic can obviously generate electric power, even though its output is limited to a very low level. A piezoelectric ceramic capable of generating electricity of a commercial grade would greatly contribute to society.

The present invention is based on experiments conducted repeatedly proving that a piezoelectric ceramic has the capacity of unexpectedly high level output power generation, and is directed to provide a power generation system that favors power generation at-site without requiring a power transmission facility by developing a piezoelectric power generator which is pollution-free and suitable for use at sites where power is required.

### MEANS TO SOLVE THE PROBLEMS

To accomplish this objective, the power generation means of the present invention provides an array of elements as a unit of power generation, which is a stack of rectangular thin piezoelectric ceramic elements for use in power generation by means of bending deformation caused by mechanical pressures, wherein the number of elements is determined such that the number yields the best pressure-deformation efficiency.

Each power generation unit, being repeatedly pressurized by a given mechanical force to cause a given flexure continuously thereof, is capable of stably generating a given level of electric energy.

### BRIEF DESCRIPTION OF THE INVENTION

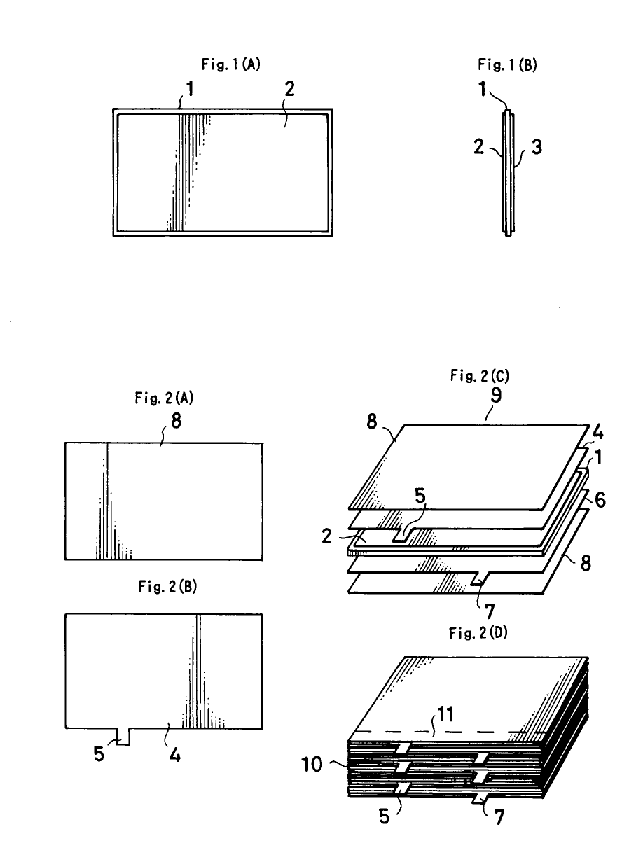

FIG. 1 is a diagram illustrating a piezoelectric ceramic element for piezoelectric power generation.

FIG. 2 is a perspective view illustrating a basic unit for piezoelectric power generation.

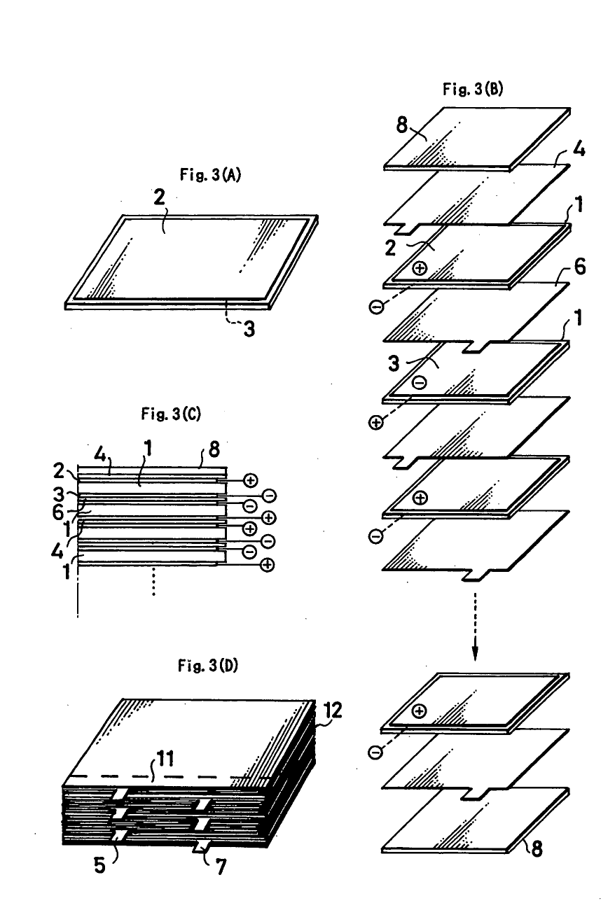

FIG. 3 is a perspective view illustrating another basic unit for piezoelectric power generation.

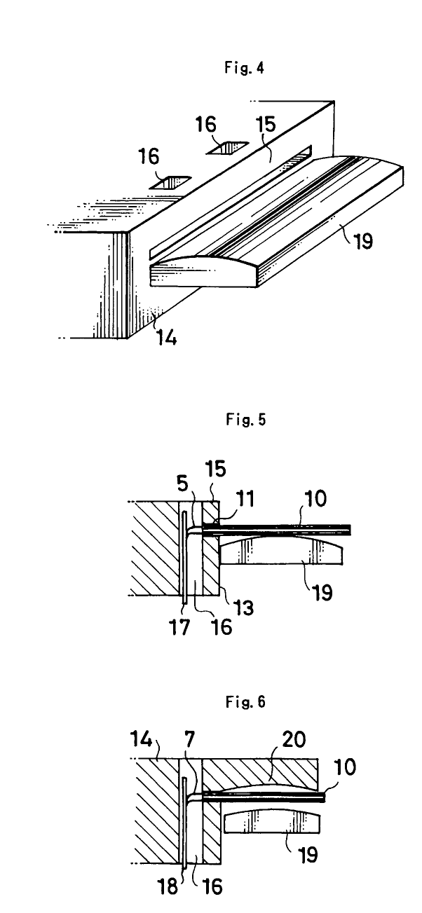

FIG. 4 is a perspective view of a part of the piezoelectric power generator of the present invention.

FIG. 5 is a cross sectional view of a holding mechanism of the power generation portion of the unit based piezoelectric power generator.

FIG. 6 a cross sectional view of another holding mechanism of the power generation portion of the unit based piezoelectric power generator.

### EMBODIMENTS

Embodiments of the present invention are described herein with reference to the drawings. FIGS. 1(A) and 1(B) illustrates a rectangular thin film piezoelectric ceramic element 1 for use in piezoelectric power generation in which metallic electrodes are formed onto both the upper and lower surfaces of the piezoelectric ceramic element 1 by baking or plating a metal having good conductance or the like to a uniform thickness and a configuration closely resembling the outline of the piezoelectric ceramic element in the proximity of but inside thereof. The electrode on the upper surface is designated as (+) electrode 2 and the electrode on the lower surface is designated as (−) electrode 3.

The rectangular thin film piezoelectric ceramic element 1 is so thin that it tends to flex.

As illustrated in FIGS. 2(A) through 2(D), a rectangular thin piezoelectric ceramic element 1 is made into an element set 9 as shown more specifically in FIG. 2(C) by attaching a (−) electrode plate 6 on the lower surface thereof and a (+) electrode plate 4 on the upper surface thereof. Multiple element sets 9 are stacked and insulation sheets 8 are inserted between each element set 9 for purposes of stabilization. Insulation sheet 8 is also attached to the top and bottom surfaces of each element set 9 such that the entire assembly provides a piezoelectric element array 10 as is shown in FIG. 2(D).

In FIGS. 3(B) and 3(C), a multiple number of rectangular thin piezoelectric ceramic elements 1 are flipped alternately such that an (−) electrode plate 6 is inserted between a (−) electrode 3 of one element and a (−) electrode 3 of another element in one element set 9 as indicated in FIG. 3(B) and FIG. 3(C) respectively, with an input terminal 7 oriented to the rear thereof as shown in FIG. 3(D). In addition, a (+) electrode plate 4 is inserted between two adjacent (+) electrodes 2 with an output terminal 5 oriented to the rear of the element 1. The surface of (+) electrode 2 of rectangular thin film piezoelectric ceramic element 1 which is on top of the element set 9 is covered by (+) spring type electrode plate 4 with insulation sheet 8 placed thereon and having the same shape as the element 1. The surface of (+) electrode 2 of the flipped rectangular thin film piezoelectric ceramic element 1 which is at the bottom of the element set 9 is pressed onto (+) spring type electrode plate 4, and an insulation sheet 8 is placed under (+) electrode plate 4, thereby forming the piezoelectric element array 12 of FIG. 3(D).

It should be understood that the output terminal 5 of (+) electrode plate 4 and the input terminal 7 of (−) electrode plate 6 of Piezoelectric element arrays 10 and 12 are arranged in opposite directions.

Piezoelectric element arrays 10 and 12 of this embodiment employ piezoelectric elements of the monomorph type. However, it should be understood that a bimorph type may also be adopted, and for the bimorph type the middle electrode plate should have a connection terminal portion similar to that of the monomorph type.

The width 11, 13 along the rear ends of each of the piezoelectric element arrays 10 and 12 constitute stationary portions which are capable of fully securing each of the piezoelectric element arrays 10 and 12, in a holding mechanism with each element array defining a basic unit of the piezoelectric power generator of the present invention.

As illustrated in FIGS. 4, 5 and 6, mounting base 14 of the holding mechanism on which element array 10 or 12 is installed, comprises: a holding jaw portion 15 having a horizontal channel 22 whose depth is equal to the total thickness of either the piezoelectric element array 10 or 12; and having a conduction circuit space 16 at the deep end of the channel 22 so as to fully house stationary portion 11, the output terminal 5, and the input terminal 7. Output electrical pickup plate 17 of FIG. 5 or output electrical pickup line and input electrical pickup plate 18 of FIG. 6 are arranged in the conduction circuit space 16 and connected to an electrical circuit in a separate compartment (not shown).

The stationary portion 11 and 13 of each piezoelectric element array 10 and 12 respectively is secured within the holding flange portion 15 of mounting base 14. All of the output terminals 5 are connected to an output electrical pickup plate 17 or output electrical pickup lines installed within conduction circuit space 16 and all input terminals 7 are connected to an input electrical pickup plate 18 or input electrical pickup lines also installed within conduction circuit space 16.

The power generation portion of the piezoelectric power generator has a movable side, which is the front side of piezoelectric element array 10 or 12, defined by the free end extension of the stationary portion 11 of piezoelectric element array 10 or the free end extension of the stationary portion 13 of piezoelectric element array 12. The stationary portions 11 and 13 are secured within the holding jaw 15 of the mounting base 14 so that the piezoelectric element array 10 or 12 is cantilevered. The front side of piezoelectric element array 10 or 12, defined as a free portion, functions as the power generation portion 19 of the piezoelectric power generator.

As illustrated in FIG. 5, the free portion or power generation portion 19 of piezoelectric element array 10 or 12 is pushed up to deform the piezoelectric element array to flex by the vertical movement of pressure element 20 which has a curved pressing surface of a length sufficient to press said free portion, lies parallel to the length direction but has a peak thereof along the center line of the curvature.

FIG. 6 shows an embodiment for protecting piezoelectric element array 10 or 12 secured onto mounting base 14 during its bending movements, in which upper jaw curvature guide 21 is provided at the upper edge of the holding jaw portion 15 of the mounting base 14 and has a curved surface of the same length as the free portion and of the same curvature as pressure element 20.

### ADVANTAGEOUS EFFECTS OF THE INVENTION

The present invention configured in the manner described above provides the following advantageous effects.

A rectangular thin film piezoelectric ceramic element 1, developed for power generation, is so thin that it flexes as an external stress is applied thereto to generate stable electric energy. Moreover, these piezoelectric ceramic elements 1 can be stacked and the stacked elements 1 flex at the same time. Additionally, stacking these piezoelectric element arrays 10 and 12 does not cause an adverse effect on the easy-to-flex characteristic thereof as long as thin plates having good conductance are adopted. Hence, electric energy generated by each of the piezoelectric elements can collectively generate electric power.

Piezoelectric element arrays 10 or 12 is cantilevered with stationary portions 11 or 13 along one edge at the rear side thereof being held secured within holding jaw 15 of mounting base 14, and the free portion 18 at the front side thereof continuously repeats its flexure motion, as pressure element 20 moves up and down, along the curvature of its curved pressing surface; the pressing surface has the same length as the free portion 18, lies parallel to the length direction of the free portion 18, and has a curvature peak on the center line in a width direction.

At this time, the use of spring type electrode plates at the top and bottom of piezoelectric element arrays 10 and 12 allows the top and bottom plates to recover from flexure caused by the up and down movement of pressure element 20.

With the assistance of upper curvature guide 21 which is provided on top of holding jaw portion 15 of the mounting base 14, when piezoelectric element array 10 or 12 flexes according to the vertical movement of pressure element 20, the degree of flexure of piezoelectric element arrays 10 and 12 is limited by the curved pressing surface of pressure element 20 and the curved surface of upper curvature guide 21 having the curvature as that of the pressure element. As a result, flexure is uniformly generated without creating spikes of the degree of flexure at specific points, thereby preventing the plates from local destruction derived from exhaustion thereof, thus enabling stabilized power generation.

Note that when pressure element 20 makes a downward movement, upper curvature guide 21 can be called a lower curvature guide, because the upper curvature guide 21 is at the lower end of holding jaw portion 15 of mounting base 14.

1. A piezoelectric power generator utilizing a square thin piezoelectric ceramic element (1) which is made by uniformly baking or plating a metal of good conductance or the like onto both the upper and lower surfaces of piezoelectric ceramic element 1 to provide electrodes such that said metallic electrodes remain in the proximity of but inside a boundary of piezoelectric ceramic element 1 wherein an electrode on the upper surface is designated as (+) electrode (2); and an electrode on the lower surface designated as (−) electrode (3).

2. A piezoelectric element array (10), which is a basic unit of piezoelectric power generation, comprising:
multiple rectangular thin film piezoelectric ceramic elements (1) as set forth in claim 1; and
a (+) electrode made of a thin plate having good conductivity is given a shape close to said rectangular thin film piezoelectric ceramic element (1) and arranged at a first end or a second end of the rear side portion of said electrode plate (4);
wherein a second piece of said electrode plate (4) is flipped putting output terminal portion (5) at the opposite end, thereby designating said (−) electrode plate (4) as electrode plate (6) and output terminal portion (5) is flipped together as output terminal portion (7); a thin film insulation sheet is shaped as a rectangle to approximate the shape of said rectangular thin film piezoelectric ceramic element (1), thereby designating said thin film insulation sheet as insulation sheet (8);
wherein said rectangular thin layer piezoelectric ceramic element (1) is made into an element set (9) by attaching a (−) electrode plate (6) on (−) electrode (3) to the lower surface thereof and a (+) electrode plate (4) on (+) electrode (2) to the upper surface thereof;
wherein multiple elements sets (9) are stacked in such a manner that insulation sheets (8) are placed between and top and bottom of the sets to stabilize electric charge thereof; the entirety of said sets are designated as piezoelectric element array (10); spring-type plates are adopted only on the top and bottom surfaces of said piezoelectric element array; and the side where input or outputs terminal are present is used as stationary portion (11), thereby providing a basic unit of power generation.

3. A piezoelectric element array (12) in which a multiple number of rectangular thin piezoelectric ceramic elements (1) are flipped alternately such that (−) electrodes (3) contact each other while (+) electrodes (2) contact each other; electrode plate (6) is inserted in the area where (−) electrodes (3) contact each other putting input terminal (7) at the rear end; (+) electrode plate (4) is inserted in the area where two (+) electrodes (2) contact each other putting output terminal (5) at the rear end; the surface of (+) electrode (2) which is on top of rectangular thin film piezoelectric ceramic element (1) is covered by a spring-type insulation sheet (8), shaped in the same manner as element (1); the surface of (+) electrode (2) which is at the bottom of the flipped rectangular thin film piezoelectric ceramic element (1) is attached to spring-type electrode plate (4) by pressure; and insulation sheet (8) is placed under (+) electrode plate (4), the side on which the input and output terminals are present, said side being utilized as stationary portion (13), which defines a basic unit for piezoelectric power generation.

4. A piezoelectric element array which utilizing a bimorph type piezoelectric element instead of the monomorph type as set forth in claim 3.

5. A power generation portion unit of the piezoelectric power generator comprising: a horizontal channel whose width is equal to the total thickness of either a piezoelectric element array (10) or (12); and a holding flange portion (15), which has a conduction circuit space (16) at the deep end of the channel so as to fully house stationary portion (11), output terminal (5), and input terminal (7); in conduction circuit space (16) are arranged an output electrical pickup plate (17) or an output electrical pickup line, and an input electrical pickup plate (18) or an input electrical pickup line, that are connected to an electrical circuit in a separate compartment; the stationary portions (11) or (13) of piezoelectric element arrays (10) or (11) is secured onto holding flange portion (15) of mounting base (14); all output terminals (5) are connected to output electrical pickup plate (17) or an output electrical pickup line installed within conduction circuit space (16); all input terminals (7) are connected to input electrical pickup plate (18) or input electrical pickup line in a similar manner; wherein said power generation portion unit of the piezoelectric power generator has a movable side, which is the front side of piezoelectric element arrays (10) or (11), defined by said movable side of stationary portion (11) of piezoelectric element array (10) or stationary portion (13) of piezoelectric element array (12), wherein stationary portions (11) and (13) are secured to holding flange (15).

6. A method of pressing the piezoelectric element of a piezoelectric power generator having a power generation unit for a piezoelectric power generator as set forth in claim 5 wherein pressure element (20), which is parallel to the length direction but has a peak thereof along the center line of curvature, moves up and down causing said movable portion to push against and flex piezoelectric element arrays (10) or (12) of power generator (19).

7. A power generation element array holding device of a rectangular thin film piezoelectric ceramic element [(1)] further comprising an upper curvature guide (21), provided on top of holding flange portion of mounting base (14) of said power generation unit of said piezoelectric power generator as set forth in claim 6; wherein said upper curvature guide (21) has the same length as the movable portion and the surface curvature thereof is equated with the surface curvature of pressure element (20).
